(19) United States
(12) Patent Application Publication
(10) Pub. No.: US 2019/0287626 A1
(43) Pub. Date: Sep. 19, 2019

(54) DATA OVERWRITING DEVICE AND DATA OVERWRITING METHOD

(71) Applicant: DENSO CORPORATION, Kariya-city, Aichi-pref. (JP)

(72) Inventors: Takuya KAWASAKI, Kariya-city (JP); Sho NAKAMURA, Kariya-city (JP); Yuzo HARATA, Kariya-city (JP); Kazuhiro UEHARA, Kariya-city (JP); Mitsuyoshi NATSUME, Kariya-city (JP); Kazuaki HAYAKAWA, Kariya-city (JP)

(73) Assignee: Denso Corporation, Kariya-city, Aichi-pref. (JP)

(21) Appl. No.: 16/318,386

(22) PCT Filed: Jun. 1, 2017
(86) PCT No.: PCT/JP2017/020464

§ 371 Date: Jan. 17, 2019

(30) Foreign Application Priority Data
Jul. 19, 2016 (JP) 2016-141344

(51) Int. Cl. G11C 16/16; G06F 11/10

(52) U.S. Cl. CPC G11C 16/16; G06F 11/1068

(57) ABSTRACT

A data overwriting device includes an overwriting unit that overwrites a part of data stored in a memory, the part in which a difference is generated; a first writing unit that writes first information in a first storage unit when a data overwriting process is completed by the overwriting unit; a second writing unit that writes second information in a second storage unit when confirming that the part of the data overwritten by the overwriting unit includes no error; and a deleting unit that clears the first storage unit storing the first information and the second storage unit storing the second information before the overwriting unit starts executing the data overwriting process.

### CROSS REFERENCE TO RELATED APPLICATION

This application is based on Japanese Patent Application No. 2016-141344 filed on Jul. 19, 2016, the disclosure of which is incorporated herein by reference.

### TECHNICAL FIELD

The present disclosure relates to a data overwriting device and a data overwriting program.

### BACKGROUND ART

Conventionally, a device for overwriting data stored in a memory is well known. For example, Patent Literature 1 discloses a technique for automatically overwriting an application program again by switching a communication program when failing to overwrite the application program stored in a memory. Patent Literature 2 discloses a technique for checking whether data is written correctly when reading out the data from a flash memory in a case where a writing failure occurs due to an influence of an instantaneous power failure or the like while writing the data into the flash memory. Patent Literature 3 discloses a technique for re-updating a program in a second nonvolatile memory when a failure occurs while updating a first nonvolatile memory.

### PRIOR ART LITERATURES

### Patent Literature

Patent Literature 1: JP-2004-005152-A

Patent Literature 2: JP-H08-006865-A

Patent Literature 3: JP-2002-351683

### SUMMARY OF INVENTION

A process of overwriting all the data stored in the memory is performed as follows. Specifically, first, all the data written in the memory is deleted. At this time, in accordance with deleting all the data, the flash status information and the stamp information stored in the memory at the time of completion of the previous data overwriting process are also deleted. Then, under a condition that the flash status information and the stamp information are deleted, the current data overwriting process starts. When the data overwriting process is completed, flash status information and stamp information are written. Thus, the data overwrite process is completed.

The flash status information is information to be written in the memory when the data overwriting process is completed. Specifically, when the flash status information is already written, it indicates that the data overwriting process is completed, and when the flash status information is not written yet, it indicates that the data overwriting process is not completed. The stamp information is information to be written in the memory when it is confirmed that the written data does not include an error. Specifically, when the stamp information is already written, it indicates that the data does not include an error, and when the stamp information is not written yet, it indicates that the data includes an error.

When overwriting all the data written in the memory, it is possible to delete the flash status information and the stamp information in accordance with deleting all the data. Thus, under a condition that the flash status information and the stamp information are deleted, the data overwriting process can be performed. Therefore, for example, when the process is interrupted during the overwriting process, since the flash status information and the stamp information are in a deleted state, it can be recognized that the status of data overwriting is incomplete, and it is possible to avoid using the data.

However, in a differential overwriting process for overwriting the data in which the difference is generated from the data written in the memory, since all the data written in the memory is not deleted, a case where the flash status information and the stamp information are not deleted may arise. Therefore, for example, when the process is interrupted during the differential overwriting process, there may occur a situation where the flash status information and the stamp information remain to be written even though the overwriting process of the differential data is not completed. In this case, since it is recognized that the data overwriting is completed, and the data does not include an error, the data may be used even though the data overwriting is incomplete.

For this reason, particularly when performing the differential overwriting process, it is required to reliably delete both the flash status information and the stamp information before the data overwriting process starts. In particular, when the data amount of the application program as an overwriting object is large, or when the memory area for storing the flash status information and the stamp information is limited, the memory area in which the application program is stored is not compressed as much as possible, and it is required to surely delete both the flash status information and the stamp information.

In view of the above, it is an object of the present disclosure to provide a data overwriting device and a data overwriting program for reliably deleting both information indicating a state that the data overwriting process has been completed before information overwriting process starts and information indicating that the written data includes no error.

According to an aspect of the present disclosure, a data overwriting device includes an overwriting unit (11), a first writing unit (12), a second writing unit (13), and a deleting unit (14). The overwriting unit overwrites a part of data stored in a memory (100), the part in which a difference is generated. The first writing unit writes predetermined first information in a first storage unit (21) when a data overwriting process is completed by the overwriting unit. The second writing unit writes predetermined second information in a second storage unit (22) when confirming that the part of the data overwritten by the overwriting unit includes no error. The deleting unit clears the first storage unit storing the first information and the second storage unit storing the second information before the overwriting unit starts executing the data overwriting process.

In one aspect of the present disclosure, a data overwriting program controls a data overwriting device to execute an overwriting step, a first writing step, a second writing step, and a deleting step. In the overwriting step, a part of data, in which a difference is generated, stored in a memory (100) is overwritten. In the first writing step, predetermined first information is written in a first storage unit (21) when the overwriting step is completed. In the second writing step, predetermined second information is written in a second storage unit (22) when confirming that the part of the data overwritten in the overwriting step includes no error. In the deleting step, the first storage unit storing the first information and the second storage unit storing the second information is cleared before starting the overwriting step.

According to the present disclosure, the first information written at the completion of the previous data overwriting process, that is, the information indicating that the data overwriting process has been completed, is reliably deleted before starting the current data overwriting process. In addition, according to the present disclosure, the second information written at the completion of the previous data overwriting process, that is, the information indicating that the overwritten data does not include an error, is reliably deleted before starting the current data overwriting process.

### BRIEF DESCRIPTION OF DRAWINGS

The above and other objects, features and advantages of the present disclosure will become more apparent from the following detailed description made with reference to the accompanying drawings. In the drawings:

FIG. 1 is a block diagram schematically showing a configuration example of a data overwriting device according to the present embodiment;

FIG. 2 is a flowchart showing an example of data overwriting process;

FIG. 3 is a diagram showing a configuration example of a memory according to the first embodiment;

FIG. 4 is a diagram showing an operation example of the first embodiment;

FIG. 5 is a diagram showing a configuration example of a memory according to a second embodiment;

FIG. 6 is a diagram showing an operation example of the second embodiment,

FIG. 7 is a diagram showing a configuration example of a memory according to a third embodiment;

FIG. 8 is a diagram showing an operation example of the third embodiment;

FIG. 9 is a diagram showing a configuration example of a memory according to a fourth embodiment;

FIG. 10 is a diagram showing an operation example of the fourth embodiment.

### EMBODIMENTS FOR CARRYING OUT INVENTION

Hereinafter, embodiments of the present disclosure relating to data overwriting device will be described with reference to attached drawings. In the following embodiments, substantially identical elements will be indicated by the same reference sign and the explanation thereof will not be skipped.

(Precedent Configuration of Data Overwriting Device)

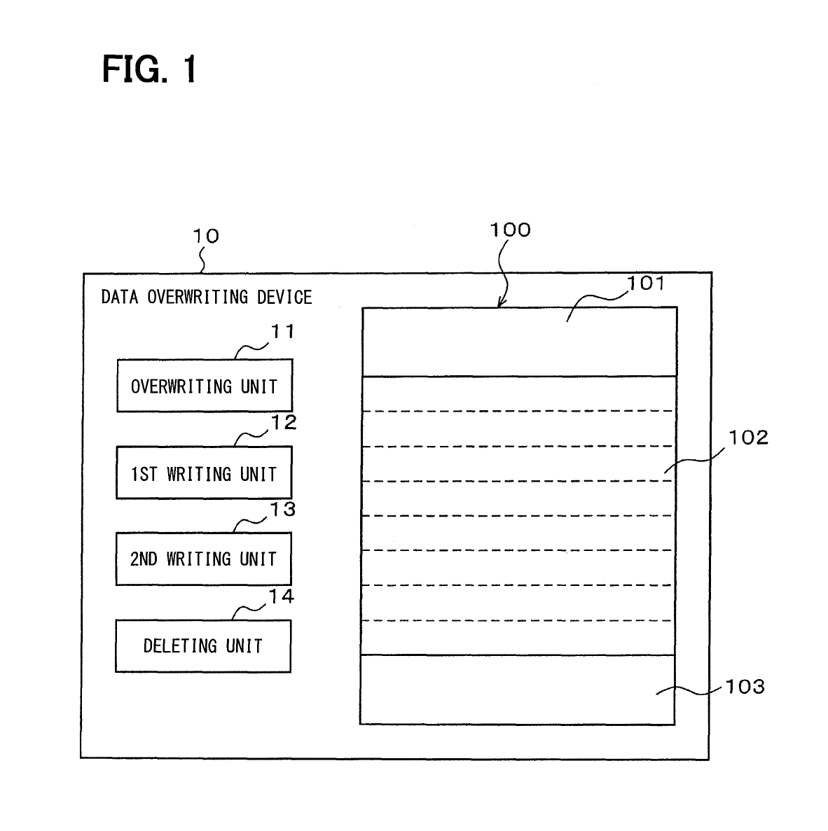

The data overwriting device 10 illustrated in FIG. 1 is a device that overwrites data written in the memory 100. In this case, the data overwriting device 10 can perform a so-called differential overwriting process for overwriting the data in which the difference is generated from the data written in the memory 100. The memory 100 includes at least three areas of an overwriting software storage unit 101, a data storage unit 102, and a saving unit 103.

The overwriting software storage unit 101 stores data overwriting software for controlling the data overwriting device 10 to execute a data overwriting process. The data overwriting software is an example of a data overwriting program. The data storage unit 102, for example, stores data constituting software used by the user and the like. The data storage unit 102 includes a plurality of block areas. The data overwriting device 10 is capable of overwriting the data stored in the data storage unit 102 in units of blocks. When the data overwriting device 10 overwrites the data stored in the data storage unit 102, particularly when only the difference is overwritten, the saving unit 103 is a region for saving temporarily a part of the data as an overwriting object data where the difference is not generated.

The data overwriting device 10 can save the data until the saving unit 103 for one block is filled with the saving data. Then, the data overwriting device 10 can execute data overwriting processing, more specifically, a generation step and a writing step of new data described later after the save portion 103 is filled with the saving data.

The data overwriting device 10 virtually realizes the overwriting unit 11, the first writing unit 12, the second writing unit 13, and the deleting unit 14 by executing the data overwriting software read out from the overwriting software storage unit 101. Here, these processing units 11 to 14 may be realized by hardware, or may be realized by a combination of software and hardware.

The overwriting unit 11 executes the overwriting process for overwriting the data stored in the data storing unit 102. In this case, the data overwriting unit 11 can perform the differential overwriting process for overwriting the data in which the difference is generated from the data written in the data storing unit 102.

After completing the data overwriting process by the overwriting unit 11, the first writing unit 12 writes the flash status information in the first storage unit 21 described later. The flash status information is an example of the first information. When the flash status information is written in the first storage unit 21, this indicates a state that the data overwriting process is completed. When the flash status information is not written in the first storage unit 21 yet, this indicates a state that the data overwriting process is not completed.

After completing the data overwriting process by the overwriting unit 11, the second writing unit 13 confirms whether the data written by the overwriting unit 11 includes an error. Then, when confirming that the data written by the overwriting unit 11 includes no error, the second writing unit 13 writes the stamp information in the second storage unit 22, which will be described later. The stamp information is an example of the second information. When the stamp information is written in the second storage unit 22, this indicates that the written data does not include an error. Further, when the stamp information is not written in the second storage unit 22, this indicates that the written data includes an error. As a method for checking whether the written data includes an error, various checking methods such as a well-known CRC method can be adopted.

Before the overwriting unit 11 starts to execute the data overwriting process, the deleting unit 14 clears the first storage unit 21 that stores the flash status information and the second storage unit 22 that stores the stamp information in block units. Specifically, the deleting unit 14 surely deletes both the flash status information and the stamp information, written in the memory 100 at the completion of the previous data overwriting process, before the current data overwriting process starts. In the data overwriting device 10 having a certain specification, the deleting unit 14 may specify the flash status information stored in the first storage unit 21 and the stamp information stored in the second storage unit 22, and delete these information with surgical precision.

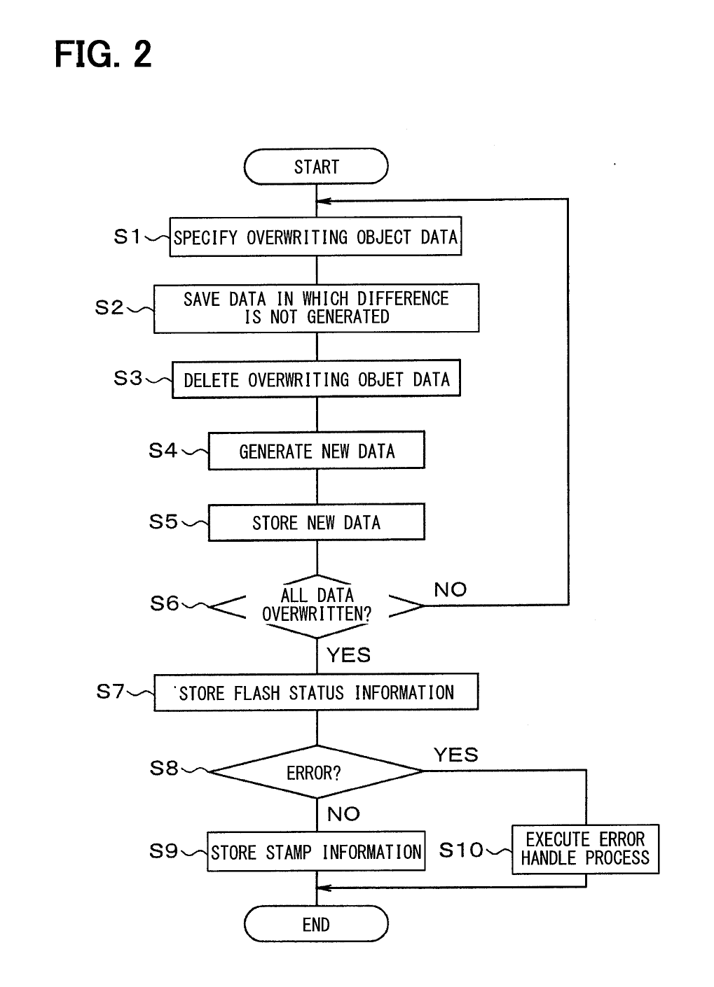

Next, an operation example of the data overwriting process executed by the data overwriting device 10 will be described. As illustrated in FIG. 2, the data overwriting device 10 specifies a block area in which data as the overwriting object data is stored when overwriting the data in which a difference is generated (at S1). Then, the data overwriting device 10 saves a part of the data, where no difference is generated from the data stored in the specified block area, into the saving unit 103 (at S 2). Then, the data overwriting device 10 deletes all the data stored in the specified block area (at S3). Then, the data overwriting device 10 combines the newly generated difference data and the part of the data saved in the saving unit 103, thereby generating new data that reflects the difference (at S 4). Then, the data overwriting device 10 stores the new data in the block area specified in step S1 (at S 5). As a result, the data overwriting device 10 overwrites the old data in which the difference is generated with the new data that reflects the difference.

The data overwriting device 10 repeatedly executes the steps A 1 to A 5 of the process for all the block areas where the difference has occurred (“No” at S 6). When overwriting the data in all the block areas where the difference has occurred (“Yes” at S 6), the data overwriting device 10 stores the flash status information in the first storage unit 21 (at S 7). Then, the data overwriting device 10 checks whether the overwritten data includes an error (at S 8). When confirming that the overwritten data does not include an error (“No” at S 8), the data overwriting device 10 stores the stamp information in the second storage unit 22 (at S 9), and the process is completed.

When an error is included in the overwritten data (“Yes” at S 8), the data overwriting device 10 executes a predetermined error handling process (at S 10). As the error handling process, for example, various processes such as a process of restarting the data overwriting process, a process of notifying by a display or a voice output that the data overwriting process has failed, a process of prohibiting the use of the data and the like can be considered.

The data overwriting device 10 having the above described prerequisite configuration can be realized in each of multiple embodiments that provide to surely delete the flash status information and the stamp information written at the time of the completion of the previous data overwriting process before starting the current data overwriting process. Each embodiment will be described as follows.

### First Embodiment

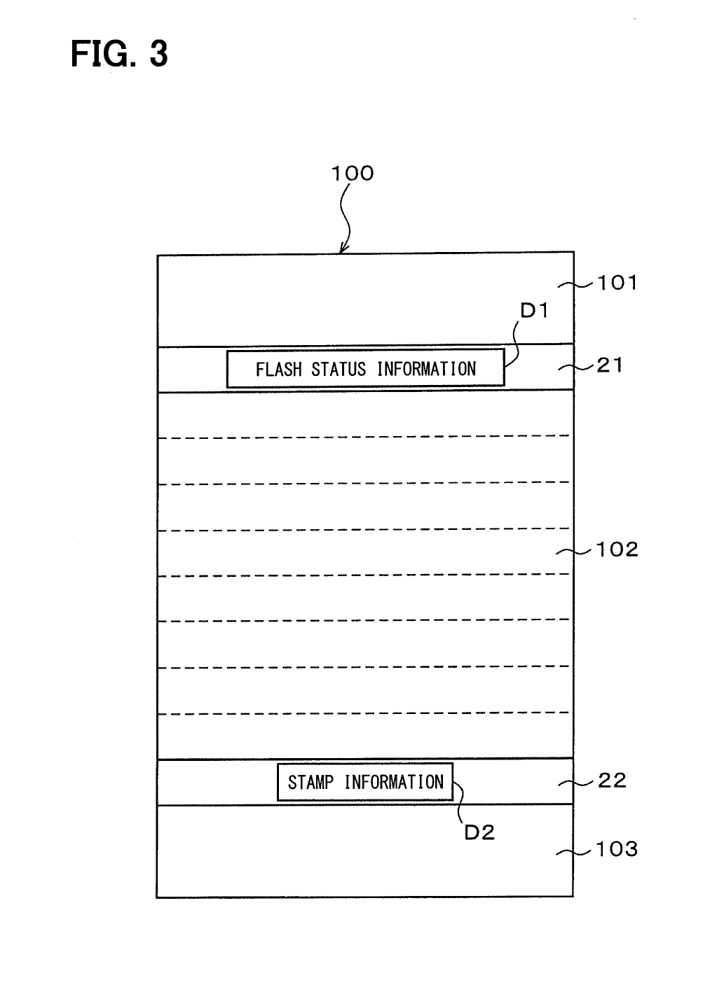

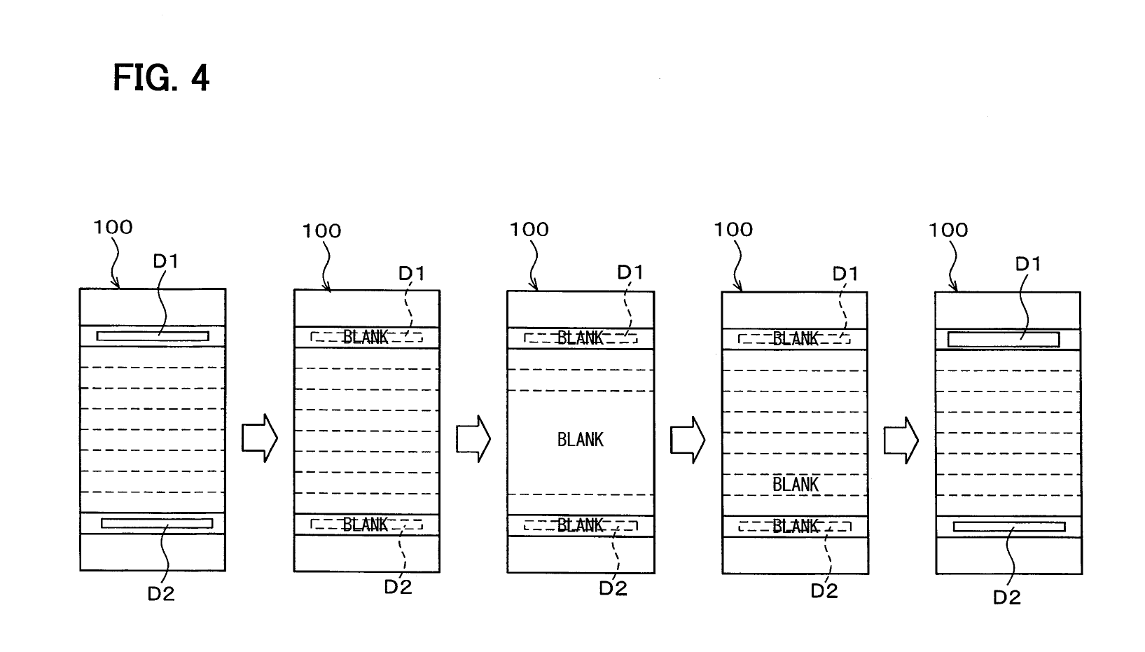

As illustrated in FIG. 3, in the present embodiment, the first storage unit 21 and the second storage unit 22 are separately arranged at an outside of the data storage unit 102. Flash status information D 1 is stored in the first storage unit 21. Stamp information D 2 is stored in the second storage unit 22. As illustrated in FIG. 4, in this case, the data overwriting device 10 firstly clears the first storage unit 21 that stores the flash status information D 1 and the second storage unit 22 that stores the stamp information D 2 in units of blocks before starting the data overwriting process. As a result, the first storage unit 21 and the second storage unit 22 are in a blank state in which no data is stored. In the data overwriting device 10 having a certain specification, the flash status information stored in the first storage unit 21 and the stamp information stored in the second storage unit 22 may be specified and deleted.

Then, the data overwriting device 10 deletes the data as the overwriting object data. Then, the data overwriting device 10 stores the new data in the block area in which the data is deleted. After completing the data overwriting process by the data overwriting device 10, the data overwriting device 10 writes the flash status information in the first storage unit 21. Then, the data overwriting device 10 checks whether the overwritten data includes an error. Then, when confirming that the written data does not include an error, the data overwriting device 10 writes the stamp information D 2 in the second storage unit 22.

According to the present embodiment, the data overwriting device 10 surely deletes the flash status information and the stamp information written at the time of the completion of the previous data overwriting process, and then, starts executing the current data overwriting process. Accordingly, when the process is interrupted during the present data overwriting process, the flash status information and the stamp information are deleted. Therefore, it can be recognized that the overwriting of data is incomplete, and it is possible to avoid using the data.

Further, the configuration of the present embodiment may be realized by securing two block areas of the block area for the first storage unit 21 and the block area for the second storage unit 22 at the outside of the data storage unit 102. Therefore, it is not necessary to greatly change the prerequisite configuration of the data overwriting device 10, and it is possible to utilize the existing configuration almost as it is.

### Second Embodiment

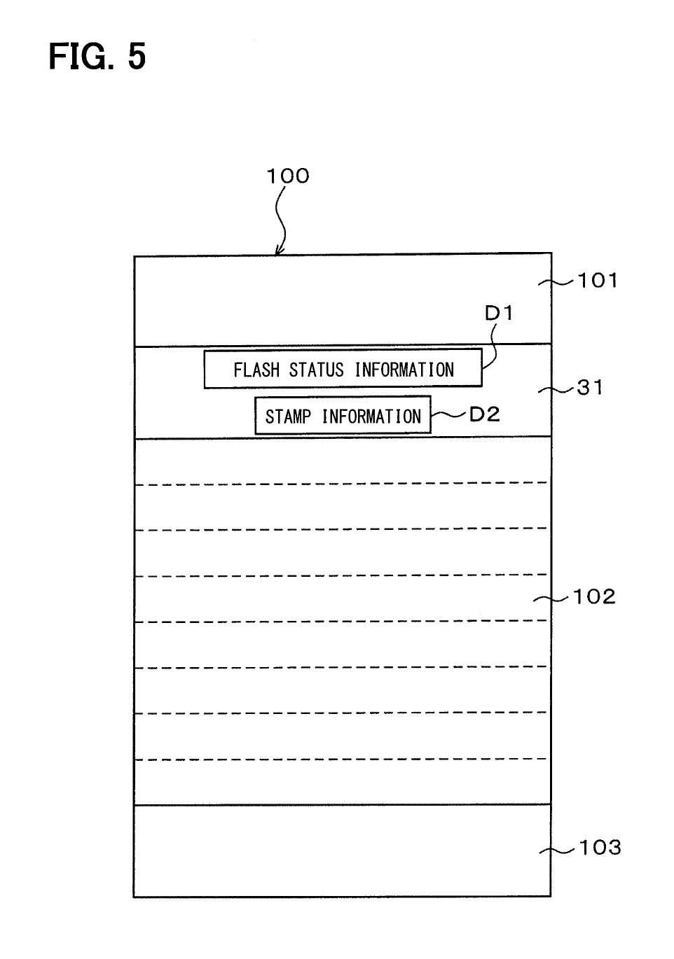

As illustrated in FIG. 5, in the present embodiment, an integrated storage unit 31 including the first storage unit 21 and the second storage unit is arranged at an outside of the data storage unit 102. Specifically, the integrated storage unit 31 functions as the first storage unit and the second storage unit, and is defined as an area where both the flash status information D 1 and the stamp information D 2 are stored.

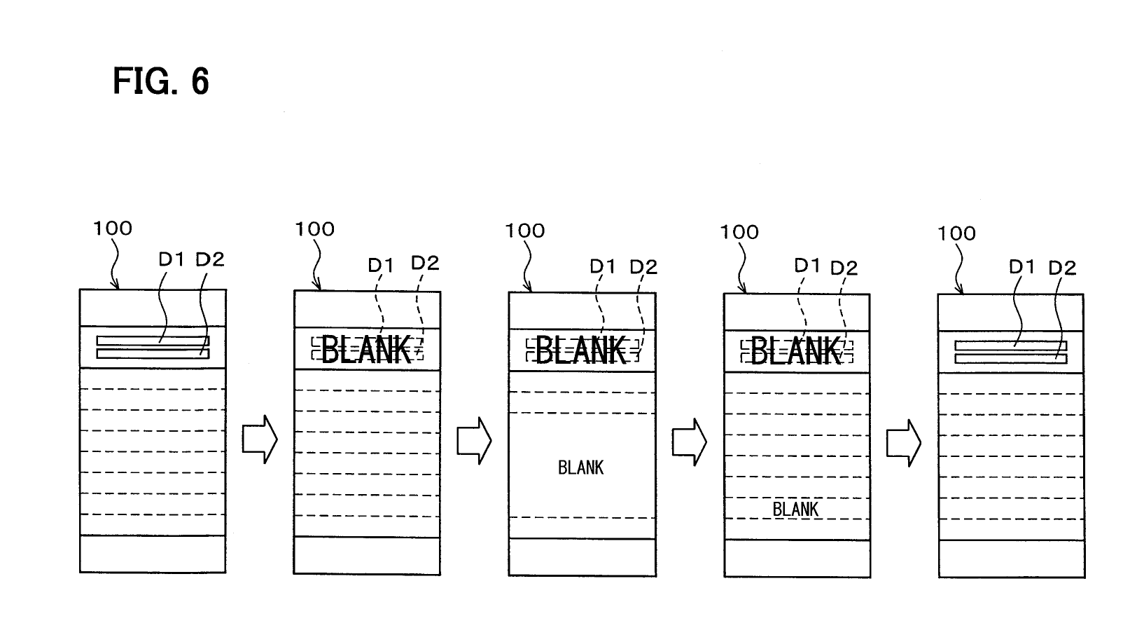

As illustrated in FIG. 6, in this case, the data overwriting device 10 firstly clears the integrated storage unit 31 that stores the flash status information D 1 and the stamp information D 2 in units of blocks before starting the data overwriting process. As a result, the integrated storage unit 31 is in a blank state in which no data is stored. In the data overwriting device 10 having a certain specification, the flash status information D1 and the stamp information D2 stored in the integrated storage unit 31 may be specified and deleted.

Then, the data overwriting device 10 deletes the data as the overwriting object data. Then, the data overwriting device 10 stores the new data in the block area in which the data is deleted. After completing the data overwriting process by the data overwriting device 10, the data overwriting device 10 writes the flash status information in the integrated storage unit 31. Then, the data overwriting device 10 checks whether the overwritten data includes an error. Then, when confirming that the written data does not include an error, the data overwriting device 10 writes the stamp information D 2 in the integrated storage unit 31.

According to the present embodiment, the data overwriting device 10 surely deletes the flash status information and the stamp information written at the time of the completion of the previous data overwriting process, and then, starts executing the current data overwriting process. Accordingly, when the process is interrupted during the present data overwriting process, the flash status information and the stamp information are deleted. Therefore, it can be recognized that the overwriting of data is incomplete, and it is possible to avoid using the data.

Further, the configuration of the present embodiment can be realized by securing a block area for the integrated storage unit 31 at the outside of the data storage unit 102. Therefore, it is not necessary to greatly change the prerequisite configuration of the data overwriting device 10, and it is possible to utilize the existing configuration almost as it is.

### Third Embodiment

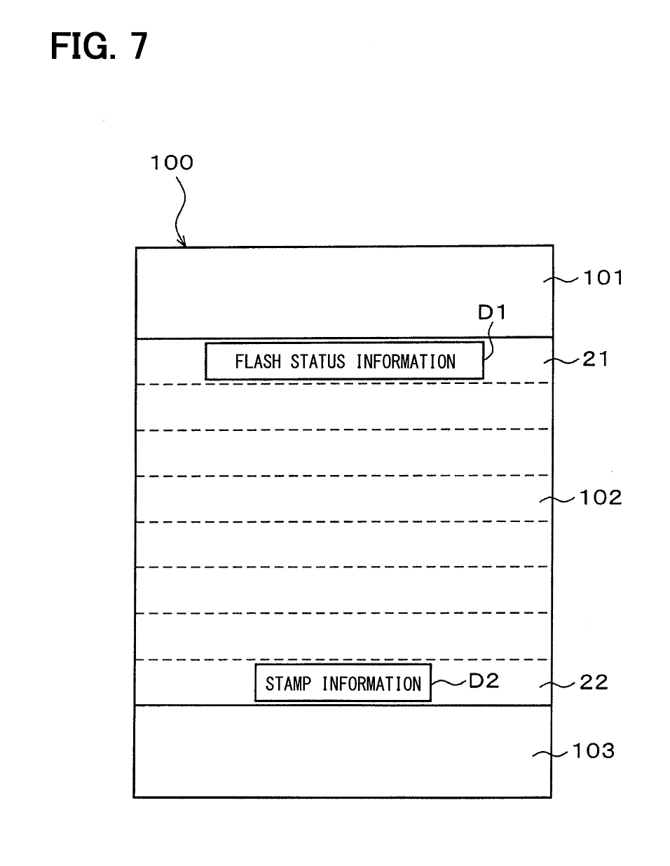

As illustrated in FIG. 7, in the present embodiment, the first storage unit 21 and the second storage unit 22 are arranged at an inside of the data storage unit 102. Specifically, in the present embodiment, the block area in the data storage unit 102 is used as the area for the first storage unit 21 and the area for the second storage unit 22. Further, in the present embodiment, the overwriting unit 11 also determines that the flash status information D 1 stored in the first storage unit 21 and the stamp information D 2 stored in the second storage unit 22 are also data in which a difference has occurred, and the overwriting unit 11 recognizes them as a part of data to be overwritten in the data overwriting process.

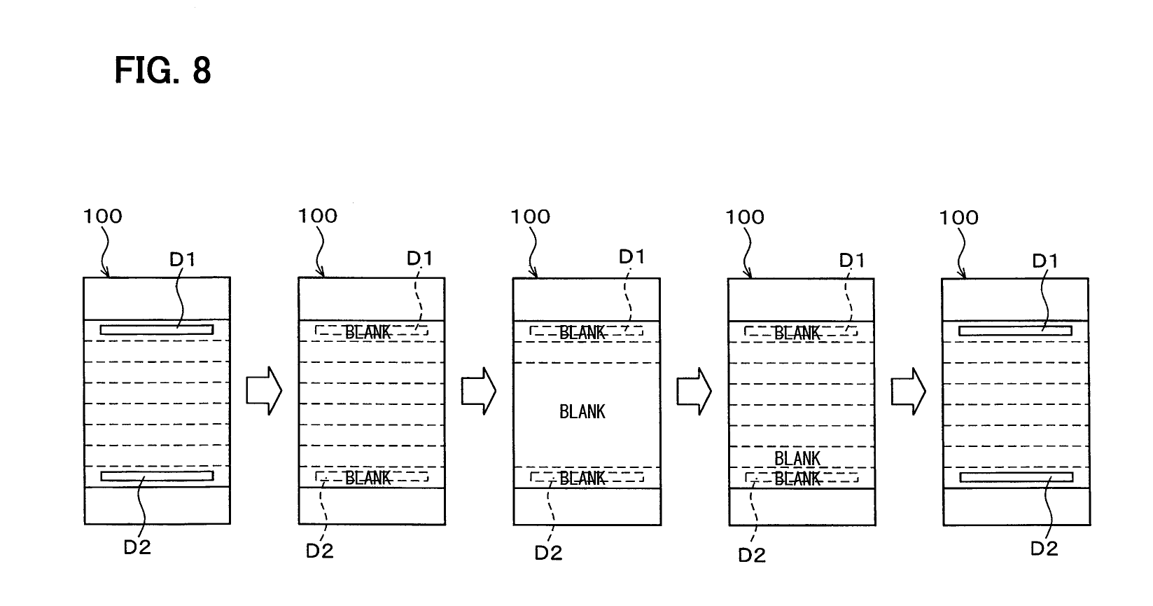

As illustrated in FIG. 8, in this case, the data overwriting device 10 firstly clears the first storage unit 21 that stores the flash status information D 1 and the second storage unit 22 that stores the stamp information D 2 in units of blocks as a part of data that is the overwriting object data before starting the data overwriting process. As a result, the first storage unit 21 and the second storage unit 22 are in a blank state in which no data is stored. In the data overwriting device 10 having a certain specification, the flash status information D1 stored in the first storage unit 21 and the stamp information D2 stored in the second storage unit 22 may be specified and deleted.

Then, the data overwriting device 10 deletes the data as the overwriting object data. Then, the data overwriting device 10 writes new data in a block area, where data is deleted, of an area other than the first storage unit 21 and the second storage unit 22. After completing the data overwriting process by the data overwriting device 10, the data overwriting device 10 writes the flash status information in the first storage unit 21. Then, the data overwriting device 10 checks whether the overwritten new data includes an error. Then, when confirming that the overwritten data does not include an error, the data overwriting device 10 writes the stamp information D 2 in the second storage unit 22.

According to the present embodiment, the data overwriting device 10 surely deletes the flash status information and the stamp information written at the time of the completion of the previous data overwriting process, and then, starts executing the current data overwriting process. Accordingly, when the process is interrupted during the present data overwriting process, the flash status information and the stamp information are deleted. Therefore, it can be recognized that the overwriting of data is incomplete, and it is possible to avoid using the data.

Further, the configuration of the present embodiment may be realized by securing two block areas of the block area for the first storage unit 21 and the block area for the second storage unit 22 at the inside of the data storage unit 102. Therefore, it is not necessary to greatly change the prerequisite configuration of the data overwriting device 10, and it is possible to utilize the existing configuration almost as it is. Further, since the existing configuration can be used as it is, it is not necessary to newly form a block area for the first storage unit 21 and a block area for the second storage unit 22. Therefore, it is possible to prevent the memory area for storing the application program from being compressed.

### Fourth Embodiment

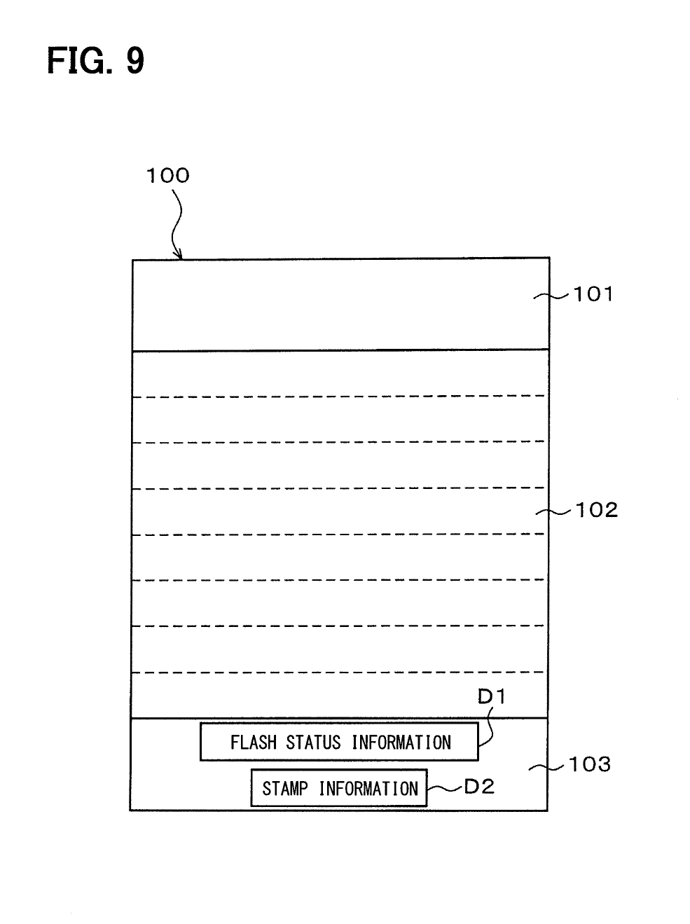

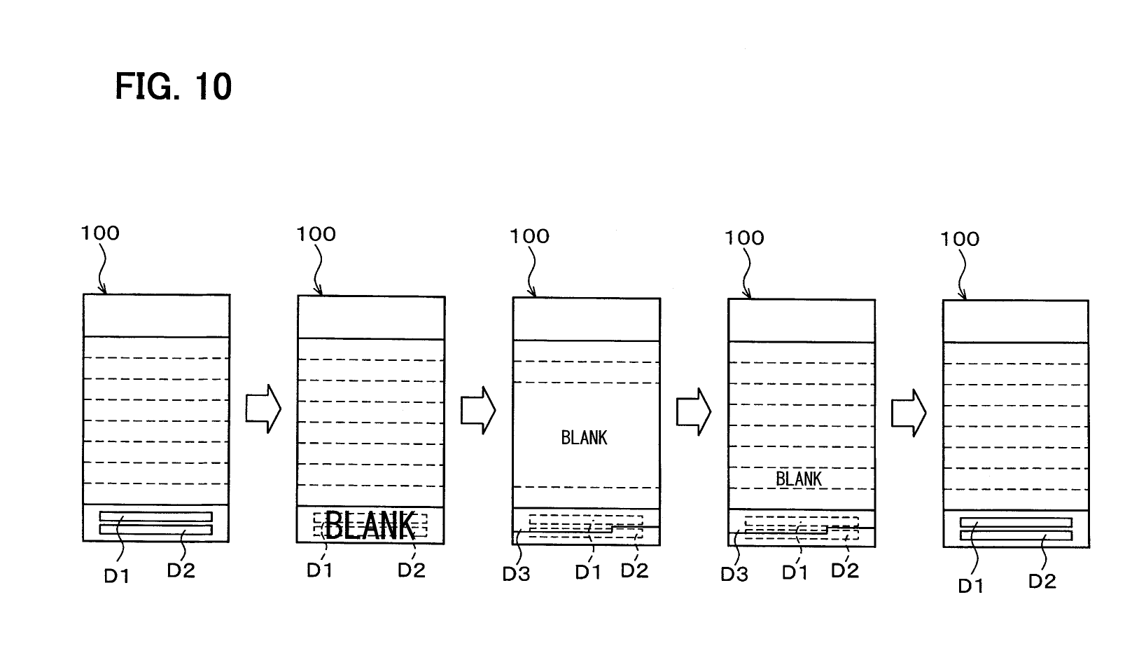

As illustrated in FIG. 9, in the present embodiment, the first storage unit 21 and the second storage unit 22 are arranged in the saving unit 103. Therefore, the saving unit 103 stores flash status information D 1 and stamp information D 2. As exemplified in FIG. 10, in this case, the data overwriting device 10 first deletes all the data stored in the save unit 103 before starting the data overwriting process. As a result, the flash status information D 1 and the stamp information D 2 stored in the saving unit 103 are also deleted, and the saving unit 103 is in a blank state in which no data is stored. In the data overwriting device 10 having a certain specification, the flash status information D1 and the stamp information D2 stored in the saving unit 103 may be specified and deleted.

Then, the data overwriting device 10 saves a part of the data, where no difference is generated, among the data as the overwriting object data, into the saving unit 103 as the saving data D3. Then, the data overwriting device 10 deletes the data as the overwriting object data. Then, the data overwriting device 10 combines the difference data with the saved data D 3 saved in the saving unit 103 to generate new data. Then, the data overwriting device 10 stores the new data in the block area in which the data is deleted. After completing the data overwriting process, the data overwriting device 10 writes the flash status information D1 in the saving unit 103. Then, the data overwriting device 10 checks whether the overwritten new data includes an error. Then, when confirming that the overwritten data does not include an error, the data overwriting device 10 writes the stamp information D 2 in the saving unit 103.

According to the present embodiment, the data overwriting device 10 surely deletes the flash status information and the stamp information written at the time of the completion of the previous data overwriting process, and then, starts executing the current data overwriting process. Accordingly, when the process is interrupted during the present data overwriting process, the flash status information and the stamp information are deleted. Therefore, it can be recognized that the overwriting of data is incomplete, and it is possible to avoid using the data.

Further, the configuration of the present embodiment can be realized by securing the first storage unit 21 and the second storage unit 22 in the save unit 103. Therefore, it is not necessary to greatly change the prerequisite configuration of the data overwriting device 10, and it is possible to utilize the existing configuration almost as it is. Further, since the existing configuration can be used as it is, it is not necessary to newly form a block area for the first storage unit 21 and a block area for the second storage unit 22. Therefore, it is possible to prevent the memory area for storing the application program from being compressed.

In the present embodiment, at least one of the same data string as the flash status information and the same data string as the stamp information is accidentally included in the data D 3 saved in the saving unit 103 may also occur. Therefore, the data overwriting device 10 may have a configuration with a function for checking whether the same data string as the flash status information D 1 and the same data string as the stamp information D 2 are included in the data D 3 to be saved in the saving unit 103.

### OTHER EMBODIMENTS

The present disclosure is not limited to the embodiments described above, and various modifications may be adopted within the scope of the present disclosure without departing from the spirit of the disclosure. For example, a plurality of the above-described embodiments may be combined as appropriate.

Although the present disclosure is described based on the above embodiment, the present disclosure is not limited to the embodiment and the structure. The present disclosure may cover various modification examples and equivalent arrangements. Furthermore, various combinations and formations, and other combinations and formations including one or more than one or less than one element may be included in the scope and the spirit of the present disclosure.

What is claimed is:

1. A data overwriting device comprising:
an overwriting unit that overwrites a part of data stored in a memory, the part in which a difference is generated;
a first writing unit that writes predetermined first information in a first storage unit when a data overwriting process is completed by the overwriting unit;
a second writing unit that writes predetermined second information in a second storage unit when confirming that the part of the data overwritten by the overwriting unit includes no error; and
a deleting unit that clears the first storage unit storing the first information and the second storage unit storing the second information before the overwriting unit starts executing the data overwriting process.

2. The data overwriting device according to claim 1, wherein:
the first storage unit and the second storage unit are disposed at an outside of an overwriting area of the memory in which the part of the data is overwritten.

3. The data overwriting device according to claim 2, wherein:
the first storage unit and the second storage unit are separately disposed at the outside of the overwriting area.

4. The data overwriting device according to claim 2, further comprising:
an integrated storage unit that includes the first storage unit and the second storage unit and disposed at an outside of the overwriting area.

5. The data overwriting device according to claim 1, wherein:
the first storage unit and the second storage unit are disposed in an overwriting area of the memory in which the part of the data is overwritten; and
the overwriting unit recognizes the first storage unit storing the first information and the second storage unit storing the second information as the part of the data to be cleared.

6. The data overwriting device according to claim 2, further comprising:
a saving unit that temporarily saves the part of the data to be overwritten by the overwriting unit, wherein:
the first storage unit and the second storage unit are disposed in the saving unit.

7. A data overwriting method comprising:
overwriting a part of data stored in a memory, the part in which a difference is generated;
writing predetermined first information in a first storage unit when the overwriting is completed;
writing predetermined second information in a second storage unit when confirming that the part of the data overwritten in the overwriting includes no error; and
clearing the first storage unit storing the first information and the second storage unit storing the second information before starting the overwriting.
